(19) United States
(12) Patent Application Publication
(10) Pub. No.: US 2021/0367399 A1
(43) Pub. Date: Nov. 25, 2021

(54) OPTICAL MODULE AND THERMOELECTRIC MODULE

(71) Applicant: FURUKAWA ELECTRIC CO., LTD., Tokyo (JP)

(72) Inventors: Yusuke INABA, Tokyo (JP); Maiko ARIGA, Tokyo (JP); Kazuki YAMAOKA, Tokyo (JP)

(73) Assignee: FURUKAWA ELECTRIC CO., LTD., Tokyo (JP)

(21) Appl. No.: 17/393,918

(22) Filed: Aug. 4, 2021

Related U.S. Application Data
(63) Continuation of application No. PCT/JP2020/003800, filed on Jan. 31, 2020.

(30) Foreign Application Priority Data
Feb. 8, 2019 (JP) 2019-021913

(51) Int. Cl. H01S 5/024

(52) U.S. Cl. CPC H01S 5/02415

(57) ABSTRACT

An optical module includes: an optical element; and a thermoelectric module on which the optical element is mounted. Further, the thermoelectric module includes a first substrate, a second substrate disposed to face the first substrate, and a plurality of thermoelectric elements provided between the first substrate and the second substrate, and a pattern made of a material different from a material of the first substrate is formed on a surface of the first substrate opposite to a back surface of the first substrate facing the second substrate, and the optical element is mounted on the surface of the first substrate in association with the pattern.

### CROSS-REFERENCE TO RELATED APPLICATION(S)

This application is a continuation of International Application No. PCT/JP2020/003800, filed on Apr. 7, 2020 which claims the benefit of priority of the prior Japanese Patent Application No. 2019-021913, filed on Feb. 8, 2019, the entire contents of which are incorporated herein by reference.

### BACKGROUND

The present invention relates to an optical module and a thermoelectric module.

As the optical module, there is disclosed an optical module configured such that a base is mounted on a Peltier module which is a thermoelectric module, and an optical element such as a semiconductor laser element, an optical isolator, or a lens is mounted on the base (see Japanese Patent Application Laid-open No. 2011-171606).

### SUMMARY

There is a need for providing an optical module and a thermoelectric module in which the height thereof is appropriately reduced.

According to an embodiment, an optical module includes: an optical element; and a thermoelectric module on which the optical element is mounted. Further, the thermoelectric module includes a first substrate, a second substrate disposed to face the first substrate, and a plurality of thermoelectric elements provided between the first substrate and the second substrate, and a pattern made of a material different from a material of the first substrate is formed on a surface of the first substrate opposite to a back surface of the first substrate facing the second substrate, and the optical element is mounted on the surface of the first substrate in association with the pattern.

According to an embodiment, a thermoelectric module includes: a first substrate; a second substrate disposed to face the first substrate; and a plurality of thermoelectric elements provided between the first substrate and the second substrate. Further, a pattern made of a material different from a material of the first substrate is formed on a surface of the first substrate opposite to a back surface of the first substrate facing the second substrate.

### BRIEF DESCRIPTION OF THE DRAWINGS

FIG. 1 is a schematic top view of an optical module according to a first embodiment;

FIG. 2 is a schematic partially cutaway side view of the optical module according to the first embodiment;

FIG. 3 is a schematic top view of the optical module according to a second embodiment;

FIG. 4 is a schematic partially cutaway side view of the optical module according to the second embodiment;

FIG. 5 is a schematic top view of the optical module according to a third embodiment;

FIG. 6 is a schematic partially cutaway side view of the optical module according to the third embodiment;

FIG. 7 is a schematic top view of the optical module according to a fourth embodiment;

FIG. 8 is a schematic partially cutaway side view of the optical module according to the fourth embodiment;

FIG. 9 is a schematic top view of the optical module according to a fifth embodiment;

FIG. 10 is a schematic partially cutaway side view of the optical module according to the fifth embodiment;

FIG. 11 is a schematic top view of the optical module according to a sixth embodiment;

FIG. 12 is a schematic partially cutaway side view of the optical module according to the sixth embodiment;

FIG. 13 is a schematic top view of a Peltier module according to a second modification;

FIG. 14 is a schematic side view of the Peltier module according to the second modification;

FIG. 15 is a schematic top view of the Peltier module according to a third modification;

FIG. 16 is a schematic side view of the Peltier module according to the third modification;

FIG. 17 is a schematic top view of the Peltier module according to a fourth modification;

FIG. 18 is a schematic side view of the Peltier module according to the fourth modification;

FIG. 19 is a schematic side view of the Peltier module according to a fifth modification;

FIG. 20 is a schematic side view of a submount according to a sixth modification; and

FIG. 21 is a schematic side view of the submount according to a seventh modification.

### DETAILED DESCRIPTION OF THE PREFERRED EMBODIMENTS

In the related art, there is an increasing demand for miniaturization of optical modules. In particular, a transmitter optical sub-assembly (TOSA) which is an optical transmission module and a receiver optical sub-assembly (ROSA) which is an optical reception module are required to be downsized, and in particular, downsizing of the size in the height direction, that is, a reduction in height is required.

Hereinafter, embodiments will be described with reference to the drawings. Note that the present invention is not limited by the embodiments. In addition, in the description of the drawings, the same or corresponding elements are appropriately denoted by the same reference numerals. In addition, it should be noted that the drawings are schematic, and a dimensional relationship between elements, a ratio of the elements, and the like may be different from reality. There may be portions having different dimensional relationships and ratios between the drawings.

In order to reduce a height of an optical module, the present inventors have studied a configuration that does not use a base. This makes it possible to reduce the height by the total thickness of a thickness of the base and a thickness of an adhesive for bonding a thermoelectric module and the base.

However, various patterns such as a metallized pattern for soldering an optical element, a wiring pattern for supplying electric power or an electric signal to the optical element, and a marker pattern for aligning the optical element are formed on a surface of the base. Therefore, in a configuration in which the base is not used, problems arise in terms of soldering, wiring, and alignment of the optical element.

Therefore, the present inventors have conceived to solve the above problems by forming a pattern on a surface of a substrate of the thermoelectric module, and completed the present invention.

### First Embodiment

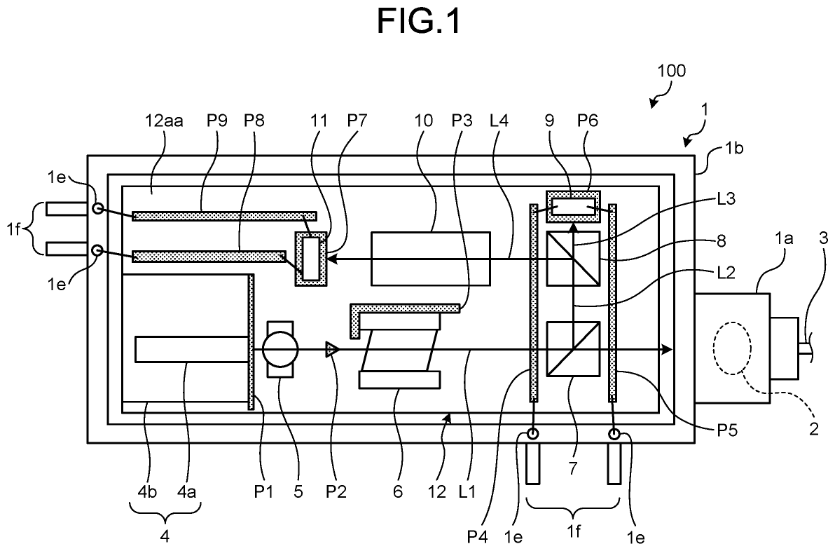

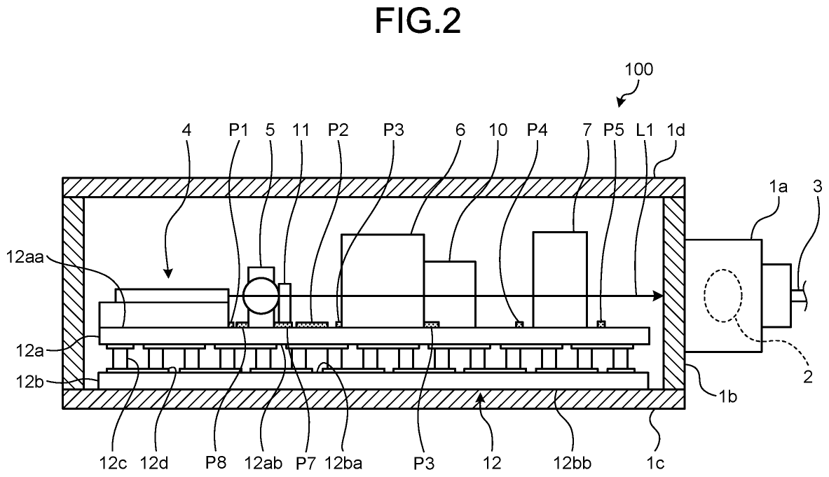

FIGS. 1 and 2 are respectively a schematic top view and a partially cutaway side view of an optical module according to a first embodiment.

An optical module 100 includes a housing 1. The housing 1 includes a signal light output port 1a, a side wall 1b, a bottom plate 1c, an upper lid 1d, a wiring portion 1e, and a lead 1f. FIG. 1 is a top view with the upper lid 1d removed. The side wall 1b is a frame plate-like member having four surfaces, and each surface is substantially orthogonal to the bottom plate 1c. The signal light output port 1a is provided on one surface of the side wall 1b. A lens 2 is accommodated in the signal light output port 1a, and an optical fiber 3 for outputting signal light to the outside is connected thereto. The bottom plate 1c is a plate-like member. The upper lid 1d is a plate-like member disposed to face the bottom plate 1c. The wiring portion 1e is provided in a part of the side wall 1b. The lead 1f is provided on the side wall 1b.

The bottom plate 1c is made of a material having high thermal conductivity, such as copper tungsten (CuW), copper molybdenum (CuMo), or aluminum oxide (Al₂O₃). The signal light output port 1a, the side wall 1b, and the upper lid 1d are made of a material having a low thermal expansion coefficient, such as an Fe—Ni—Co alloy or aluminum oxide (Al₂O₃). The wiring portion 1e is made of an insulating material, and a wiring pattern made of a conductor is formed. The lead 1f is made of a conductor. In the present embodiment, the lead 1f is a lead pin, but may have a pad shape.

The lead 1f is electrically connected to a controller provided outside the optical module 100. The controller controls an operation of the optical module 100. The controller is configured to include, for example, an integrated circuit (IC).

The following components are accommodated inside the optical module 100: a chip-on-submount 4, a lens 5, an optical isolator 6, beam splitters 7 and 8, a monitor photodiode (PD) 9 which is a light receiving element, an etalon filter 10, a monitor PD 11, and a Peltier module 12. The beam splitters 7 and 8 may be configured to include a prism or a mirror.

In the optical module 100, the components are mounted inside the housing 1, and are hermetically sealed by attaching the upper lid 1d.

The optical module 100 is configured as a semiconductor laser module. Hereinafter, the configuration and function of each component will be described.

The Peltier module 12, which is the thermoelectric module, includes a first substrate 12a, a second substrate 12b, a plurality of thermoelectric elements 12c, and a wiring pattern 12d.

The first substrate 12a is made of an insulating material having high thermal conductivity such as ceramic, and has a front surface 12aa and a back surface 12ab facing the front surface 12aa as main surfaces. The second substrate 12b is made of the insulating material having high thermal conductivity such as ceramic, and has a front surface 12ba and a back surface 12bb facing the front surface 12aa as main surfaces. The second substrate 12b is disposed such that its front surface 12ba faces the back surface 12ab of the first substrate 12a. The Peltier module 12 is fixed to the bottom plate 1c on the back surface 12bb of the second substrate 12b.

Each of the thermoelectric elements 12c is a columnar semiconductor element provided between the first substrate 12a and the second substrate 12b. Each of the thermoelectric elements 12c is made of a P-type semiconductor or an N-type semiconductor, but is made of, for example, a bismuth tellurium semiconductor. The thermoelectric elements 12c are connected in series so as to form a PN junction by the wiring pattern 12d. The wiring pattern 12d is a pattern formed on the back surface 12ab of the first substrate 12a and the front surface 12ba of the second substrate 12b and made of a conductor such as metal. Thus, the Peltier module 12 absorbs heat or generates heat according to a direction in which a current flows. Note that the current flowing through the Peltier module 12 is supplied from the outside via a lead (not illustrated).

The chip-on-submount 4, the lens 5, the optical isolator 6, the beam splitters 7 and 8, the monitor PD 9, the etalon filter 10, and the monitor PD 11 are mounted on the front surface 12aa of the first substrate 12a of the Peltier module 12. The components are controlled to a desired temperature by passing the current through the Peltier module 12.

The chip-on-submount 4 includes a laser element 4a and a submount 4b on which the laser element 4a is mounted. The laser element 4a is a semiconductor laser element, for example, a wavelength-tunable laser element. The submount 4b is made of the insulating material having high thermal conductivity, and efficiently transports heat generated by the laser element 4a to the Peltier module 12.

The laser element 4a is supplied with power from the outside via a lead (not illustrated), and outputs a laser beam L1 to the signal light output port 1a side.

The lens 5 collimates the laser beam L1 and outputs it to the optical isolator 6. The optical isolator 6 allows the laser beam L1 to pass to the beam splitter 7 side and blocks light traveling from the beam splitter 7 side. Thus, the optical isolator 6 prevents reflected light or the like from being input to the laser element 4a.

The beam splitter 7 outputs most of the laser beam L1 having passed through the optical isolator 6 to the lens 2, and outputs a part of the laser beam L1 as a laser beam L2 to a beam splitter 8. The lens 2 condenses and couples the input laser beam L1 to the optical fiber 3.

The beam splitter 8 splits the laser beam L2 into laser beams L3 and L4, outputs the laser beam L3 to the monitor PD 9, and outputs the laser beam L4 to the etalon filter 10. The monitor PD 9 receives the laser beam L3 and outputs a current signal corresponding to received light intensity. The current signal is transmitted to the controller and used for detection and control of power and wavelength of the laser beam L1.

The etalon filter 10 is a filter whose transmission characteristic periodically changes with respect to the wavelength. The etalon filter 10 transmits the laser beam L4 with a transmittance corresponding to the wavelength, and outputs it to the monitor PD 11. The monitor PD 11 receives the laser beam L4 transmitted through the etalon filter 10 and outputs the current signal corresponding to the received light intensity. The current signal is transmitted to the controller and used for detection and control of the wavelength of the laser beam L1.

Here, patterns P1 to P9 made of a material different from that of the first substrate 12a are formed on the front surface 12aa of the first substrate 12a. The patterns P1 to P9 are made of, for example, at least one of a metal, a dielectric, or a resin according to the application. Optical elements such as the laser element 4a, the lens 5, the optical isolator 6, the beam splitters 7 and 8, and the monitor PDs 9 and 11 of the chip-on-submount 4 are mounted in association with any of the patterns.

For example, the pattern P1 functions as a marker for positioning when the chip-on-submount 4 is mounted on the Peltier module 12 and fixed with a thermally conductive material. Therefore, the pattern P1 is associated with the laser element 4a. Note that examples of the thermally conductive material for fixing the chip-on-submount 4 to the Peltier module 12 include solder and a thermally conductive resin. The pattern P1 also functions as a flow stopper until the thermally conductive material is cured. In this case, the pattern P1 preferably has a thickness enough to function as the flow stopper.

The pattern P2 functions as a marker for adjusting an optical axis of the laser beam L1. Therefore, the pattern P2 is associated with the laser element 4a and the lens 5.

The pattern P3 functions as the marker for positioning the optical isolator 6. Therefore, the pattern P3 is associated with the optical isolator 6. Note that as an adhesive for fixing the optical isolator 6 to the Peltier module 12, an epoxy resin is exemplified. The pattern P3 also functions as the flow stopper that prevents the adhesive from flowing to an unnecessary place until the adhesive is cured. In this case, the pattern P3 preferably has the thickness enough to function as the flow stopper.

The patterns P4 and P5 function as the wiring patterns for outputting the current signal from the monitor PD 9 to the outside via the wiring portion 1e and the lead 1f. The monitor PD 9 and the patterns P4 and P5 are connected by bonding wires. In addition, the pattern P6 functions as the base for soldering the monitor PD 9 and the marker for alignment. Therefore, the patterns P4 to P6 are associated with the monitor PD 9. Note that the patterns P4 to P6 are preferably metallized patterns. The metallized pattern is preferably made of gold (Au). In addition, it may have a structure of two or more layers in which a gold (Au) layer and a layer including at least one of copper (Cu), titanium (Ti), nickel (Ni), palladium (Pd), and platinum (Pt) are laminated.

Further, when the beam splitters 7 and 8 are fixed to the Peltier module 12 with the adhesive, the patterns P4 and P5 also function as the flow stoppers until the adhesive is cured. In this case, the patterns P4 and P5 preferably have thicknesses enough to function as the flow stoppers.

The pattern P7 functions as the base for soldering the monitor PD 11 and the marker for alignment. The patterns P8 and P9 function as the wiring patterns for outputting the current signal from the monitor PD 11 to the outside via the wiring portion 1e and the lead 1f. The monitor PD 11 and the patterns P8 and P9 are connected by the bonding wires. Therefore, the patterns P7 to P9 are associated with the monitor PD 11. Note that the patterns P7 to P9 are preferably the metallized patterns.

According to the optical module 100, by directly mounting the component without the base, a reduction in height can be realized, and wiring, soldering, and alignment of the optical element to be mounted can be suitably realized.

### Second Embodiment

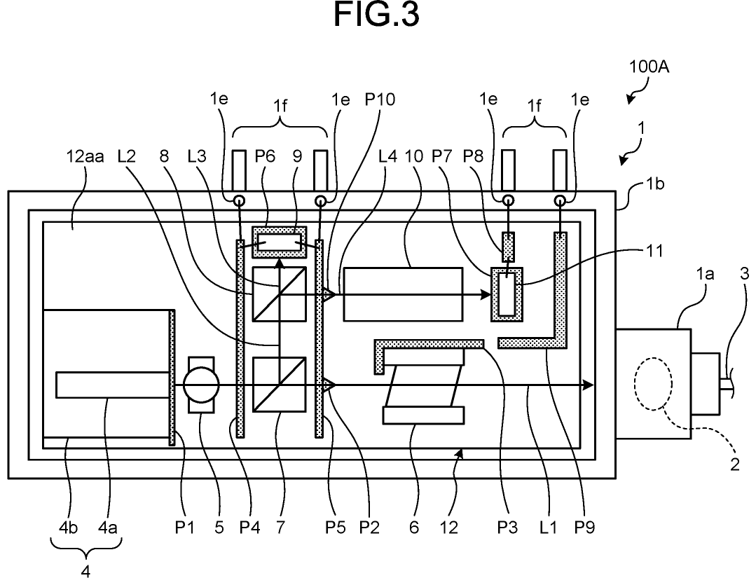

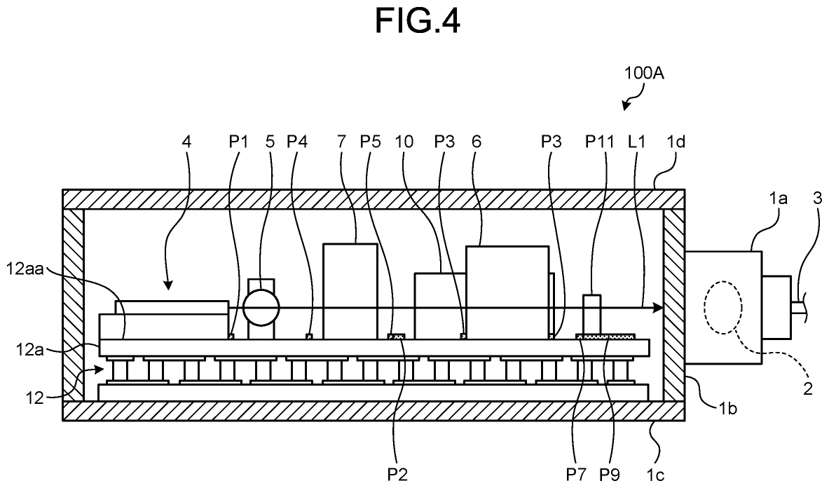

FIGS. 3 and 4 are respectively a schematic top view and a partially cutaway side view of the optical module according to a second embodiment.

This optical module 100A includes the housing 1 similar to that of the optical module illustrated in FIG. 1. The housing 1 includes a signal light output port 1a, a side wall 1b, a bottom plate 1c, an upper lid 1d, a wiring portion 1e, and a lead 1f.

The following components are accommodated inside the optical module 100A: a chip-on-submount 4, the lens 5, the optical isolator 6, the beam splitters 7 and 8, the monitor PD 9, the etalon filter 10, the monitor PD 11, and the Peltier module 12.

In the optical module 100A, the components are mounted inside the housing 1, and are hermetically sealed by attaching the upper lid 1d.

The optical module 100A is configured as the semiconductor laser module. Hereinafter, the configuration and function of each component will be described. However, description of components having the same configuration and function as those in the first embodiment will be omitted as appropriate.

The Peltier module 12 absorbs heat or generates heat according to the direction in which the current flows.

The chip-on-submount 4, the lens 5, the optical isolator 6, the beam splitters 7 and 8, the monitor PD 9, the etalon filter 10, and the monitor PD 11 are mounted on the front surface 12aa of the first substrate 12a of the Peltier module 12, and are controlled to the desired temperature by the Peltier module 12.

The laser element 4a of the chip-on-submount 4 outputs the laser beam L1 to the signal light output port 1a side.

The lens 5 collimates the laser beam L1 and outputs it to the beam splitter 7. The beam splitter 7 outputs most of the laser beam L1 to the optical isolator 6, and outputs a part of the laser beam L1 as the laser beam L2 to the beam splitter 8. The optical isolator 6 allows the laser beam L1 to pass to the lens 2 side. The lens 2 condenses and couples the input laser beam L1 to the optical fiber 3.

The beam splitter 8, the monitor PD 9, the etalon filter 10, and the monitor PD 11 have the same configuration and function as in the first embodiment.

Here, the patterns P1 to P10 made of a material different from that of the first substrate 12a are formed on the front surface 12aa of the first substrate 12a. The patterns P1 to P10 are made of, for example, at least one of the metal, the dielectric, or the resin according to the application.

The patterns P1 to P9 have the same functions as those in the first embodiment. The pattern P10 functions as a marker for adjusting the optical axis of the laser beam L4. Therefore, the pattern P10 is associated with the beam splitter 8 and the etalon filter 10.

According to the optical module 100A, the reduction in height can be realized, and the wiring, the soldering, and the alignment of the optical element to be mounted can be suitably realized.

### Third Embodiment

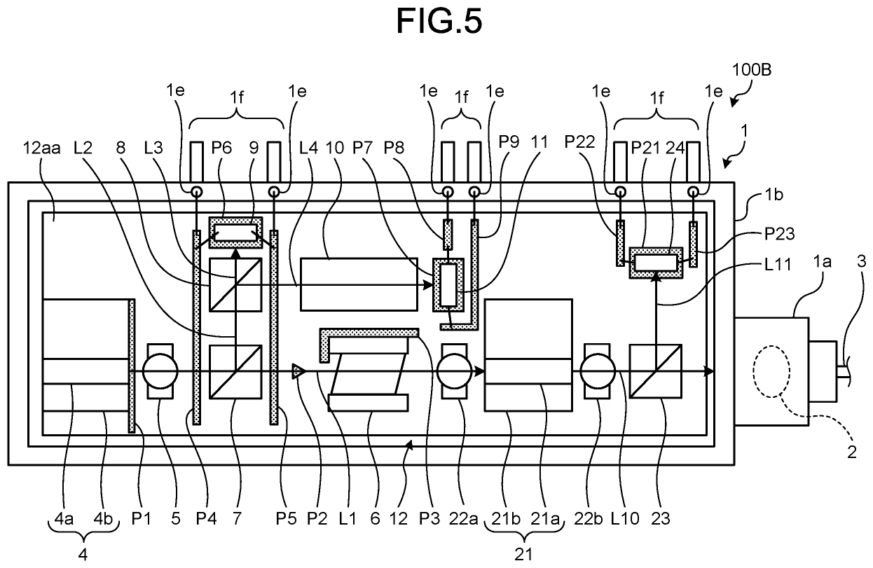

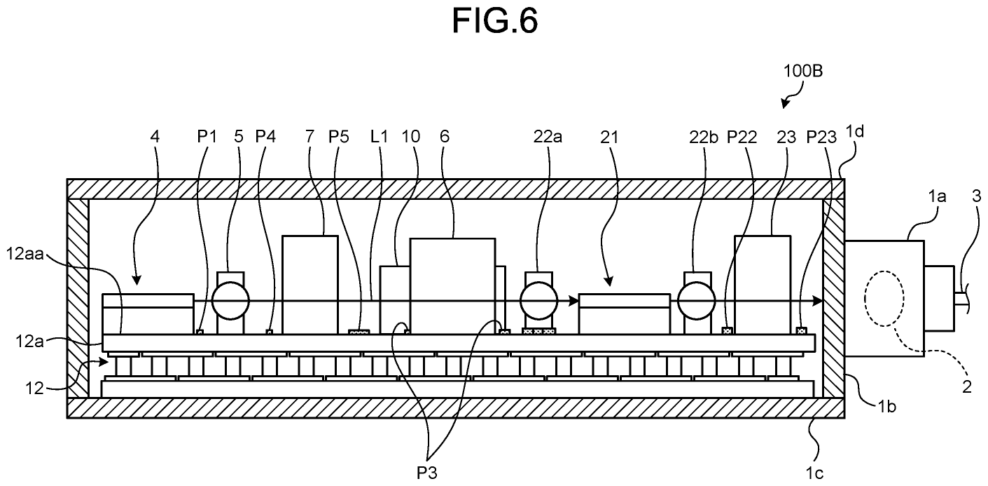

FIGS. 5 and 6 are respectively a schematic top view and a partially cutaway side view of the optical module according to a third embodiment.

This optical module 100B includes the housing 1 similar to that of the optical module illustrated in FIG. 1. The housing 1 includes a signal light output port 1a, a side wall 1b, a bottom plate 1c, an upper lid 1d, a wiring portion 1e, and a lead 1f.

The following components are accommodated inside the optical module 100B: the chip-on-submount 4, the lens 5, the optical isolator 6, the beam splitters 7 and 8, the monitor PD 9, the etalon filter 10, the monitor PD 11, and the Peltier module 12. Further, the following components are accommodated inside the optical module 100B: a chip-on-submount 21, lenses 22a and 22b, a beam splitter 23, and a monitor PD 24.

In the optical module 100B, the components are mounted inside the housing 1, and are hermetically sealed by attaching the upper lid 1d.

The optical module 100B is configured as the semiconductor laser module. Hereinafter, the configuration and function of each component will be described. However, the description of the components having the same configuration and function as those in other embodiments will be omitted as appropriate.

The Peltier module 12 absorbs heat or generates heat according to the direction in which the current flows.

The chip-on-submount 4, the lens 5, the optical isolator 6, the beam splitters 7 and 8, the monitor PD 9, the etalon filter 10, the monitor PD 11, the chip-on-submount 21, the lenses 22a and 22b, the beam splitter 23, and the monitor PD 24 are mounted on the front surface 12aa of the first substrate 12a of the Peltier module 12, and are controlled to the desired temperature by the Peltier module 12.

The chip-on-submount 4, the lens 5, the beam splitter 7, the beam splitter 8, the monitor PD 9, the etalon filter 10, and the monitor PD 11 have the same configuration and function as those in the other embodiments.

The optical isolator 6 allows the laser beam L1 to pass to the chip-on-submount 21 side. The chip-on-submount 21 includes a semiconductor optical amplifier 21a and a submount 21b on which the semiconductor optical amplifier 21a is mounted. The submount 21b is made of the insulating material having high thermal conductivity, and efficiently transfers heat generated by the semiconductor optical amplifier 21a to the Peltier module 12. The submount 21b is fixed to the Peltier module 12 with the thermally conductive material.

The semiconductor optical amplifier 21a is supplied with power from the outside via a lead (not illustrated), optically amplifies the laser beam L1 condensed by the lens 22a and input from the optical isolator 6, and outputs it as a laser beam L10 to the signal light output port 1a side.

The lens 22b collimates the laser beam L10 and outputs it to the beam splitter 23. The beam splitter 23 outputs most of the laser beam L10 to the lens 2 and outputs a part of the laser beam L10 as a laser beam L11 to the monitor PD 24. The lens 2 condenses and couples the input laser beam L10 to the optical fiber 3.

The monitor PD 24 receives the laser beam L11 and outputs the current signal corresponding to the received light intensity. The current signal is transmitted to the controller and used for detection and control of the power of the laser beam L10.

Here, patterns P1 to P9 and P21 to P23 made of a material different from that of the first substrate 12a are formed on the front surface 12aa of the first substrate 12a. The patterns P1 to P9 and P21 to P23 are made of, for example, at least one of the metal, the dielectric, or the resin according to the application.

The patterns P1 to P9 have the same functions as those of the other embodiments. The pattern P21 functions as the base for soldering the monitor PD 24 and the marker for alignment. The patterns P22 and P23 function as the wiring patterns for outputting the current signal from the monitor PD 24 to the outside via the wiring portion 1e and the lead 1f. The monitor PD 24 and the patterns P22 and P23 are connected by the bonding wires. Therefore, the patterns P21 to P23 are associated with the monitor PD 24. The patterns P21 to P23 are preferably the metallized patterns.

According to the optical module 100B, the reduction in height can be realized, and the wiring, the soldering, and the alignment of the optical element to be mounted can be suitably realized. In addition, since the semiconductor optical amplifier 21a is provided, the laser beam having higher power can be output.

### Fourth Embodiment

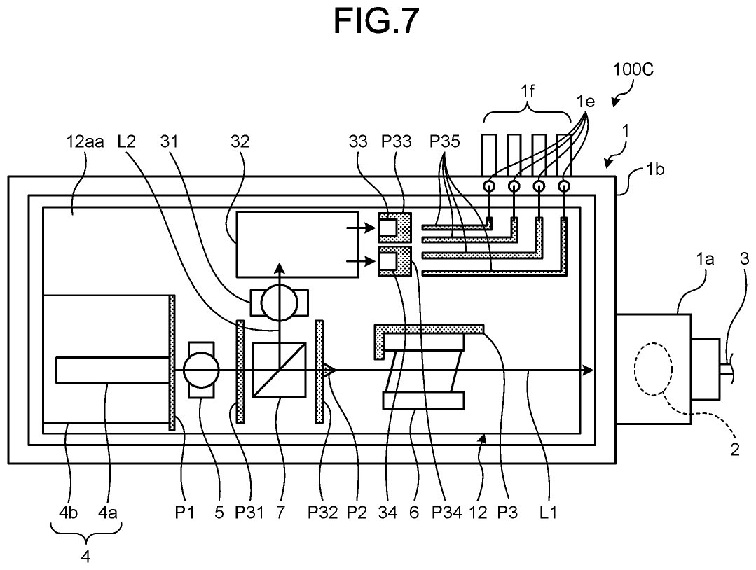

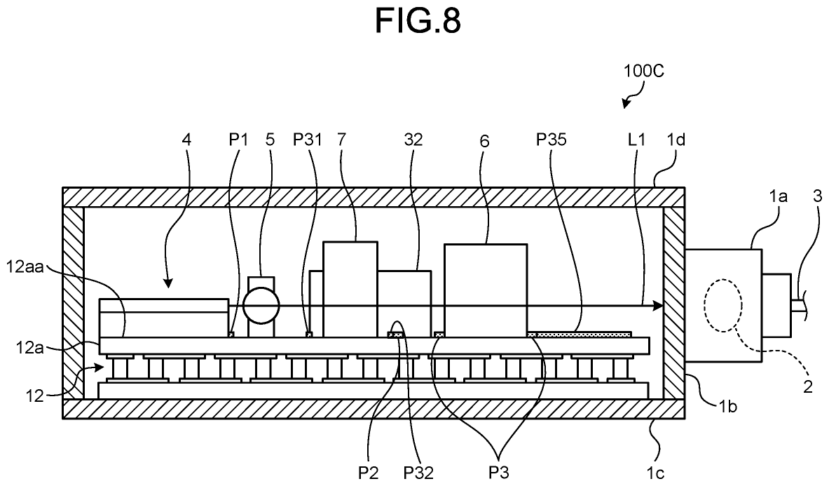

FIGS. 7 and 8 are respectively a schematic top view and a partially cutaway side view of the optical module according to a fourth embodiment.

The optical module 100C includes the housing 1 similar to that of the optical module illustrated in FIG. 1. The housing 1 includes a signal light output port 1a, a side wall 1b, a bottom plate 1c, an upper lid 1d, a wiring portion 1e, and a lead 1f.

The following components are housed inside the optical module 100C: the chip-on-submount 4, the lens 5, the optical isolator 6, the beam splitter 7, a lens 31, a wavelength locker 32, monitor PDs 33 and 34, and the Peltier module 12.

In the optical module 100C, the components are mounted inside the housing 1, and are hermetically sealed by attaching the upper lid 1d.

The optical module 100C is configured as the semiconductor laser module. Hereinafter, the configuration and function of each component will be described. However, the description of the components having the same configuration and function as those in other embodiments will be omitted as appropriate.

The Peltier module 12 absorbs heat or generates heat according to the direction in which the current flows.

The chip-on-submount 4, the lens 5, the optical isolator 6, the beam splitter 7, the lens 31, the wavelength locker 32, and the monitor PDs 33 and 34 are mounted on the front surface 12aa of the first substrate 12a of the Peltier module 12, and are controlled to the desired temperature by the Peltier module 12.

The chip-on-submount 4 and the lens 5 have the same configuration and function as those of the other embodiments. The beam splitter 7 outputs most of the laser beam L1 output from the lens 5 to the optical isolator 6, and outputs a part of the laser beam L1 as the laser beam L2 to the lens 31. The optical isolator 6 allows the laser beam L1 to pass to the lens 2 side. The lens 2 condenses and couples the input laser beam L1 to the optical fiber 3.

The lens 31 condenses the laser beam L2 and inputs it to the wavelength locker 32. The wavelength locker 32 is a known one including, for example, a planar lightwave circuit (PLC) using quartz-based glass as a constituent material. The wavelength locker 32 branches the laser beam L2 into two beams, outputs one of the beams to the monitor PD 33, and outputs the other beam to the monitor PD 34 after causing the other beam to pass through the filter whose transmission characteristic periodically changes with respect to the wavelength. The filter includes, for example, a ring resonator having an optical waveguide structure.

Each of the monitor PDs 33 and 34 receives each of two laser beams output from the wavelength locker 32 and outputs the current signal corresponding to the received light intensity. Each current signal is transmitted to the controller and used for detection and control of the wavelength of the laser beam L1.

Here, the patterns P1 to P3 and P31 to P35 made of a material different from that of the first substrate 12a are formed on the front surface 12aa of the first substrate 12a. The patterns P1 to P3 and P31 to P35 are made of, for example, at least one of the metal, the dielectric, or the resin according to the application.

The patterns P1 to P3 have the same functions as those of the other embodiments. When the beam splitter 7 is fixed to the Peltier module 12 with the adhesive, the patterns P31 and P32 function as the flow stoppers until the adhesive is cured.

The patterns P33 and P34 function as the base for soldering the monitor PDs 33 and 34 and the marker for alignment. The pattern P35 functions as a wiring pattern for outputting current signals from the monitor PDs 33 and 34 to the outside via the wiring portion 1e and the lead 1f.

According to the optical module 100C, the reduction in height can be realized, and the wiring, the soldering, and the alignment of the optical element to be mounted can be suitably realized.

### Fifth Embodiment

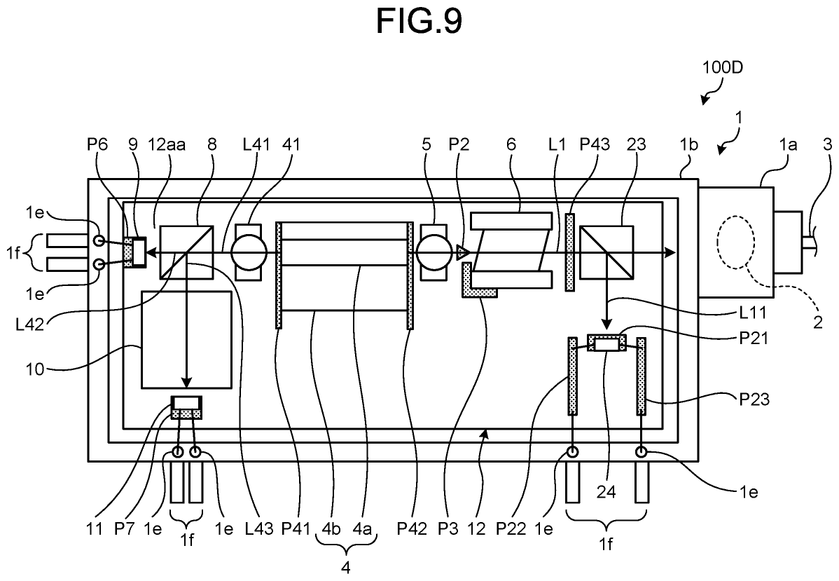

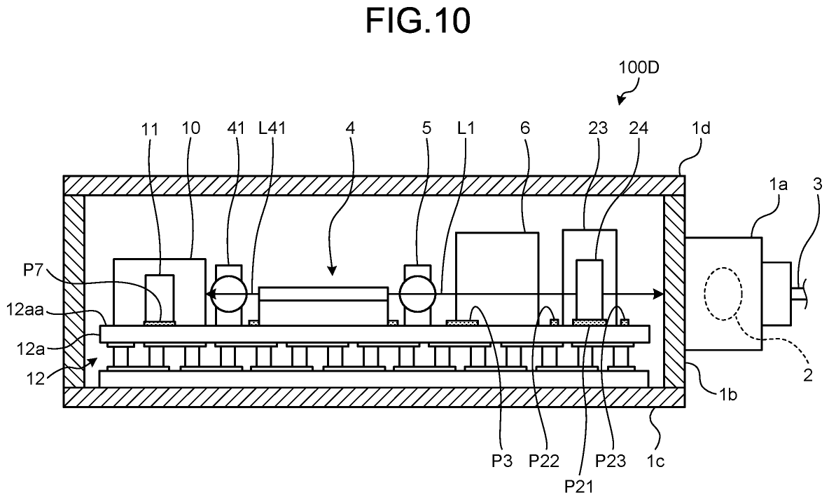

FIGS. 9 and 10 are respectively a schematic top view and a partially cutaway side view of the optical module according to a fifth embodiment.

This optical module 100D includes the housing 1 similar to that of the optical module illustrated in FIG. 1. The housing 1 includes a signal light output port 1a, a side wall 1b, a bottom plate 1c, an upper lid 1d, a wiring portion 1e, and a lead 1f.

The following components are accommodated inside the optical module 100 D: the chip-on-submount 4, the lens 5, the optical isolator 6, the beam splitter 8, the etalon filter 10, the monitor PDs 9 and 11, the beam splitter 23, the monitor PD 24, a lens 41, and the Peltier module 12.

In the optical module 100D, the components are mounted inside the housing 1, and are hermetically sealed by attaching the upper lid 1d.

The optical module 100D is configured as the semiconductor laser module. Hereinafter, the configuration and function of each component will be described. However, the description of the components having the same configuration and function as those in other embodiments will be omitted as appropriate.

The Peltier module 12 absorbs heat or generates heat according to the direction in which the current flows.

The chip-on-submount 4, the lens 5, the optical isolator 6, the beam splitter 8, the etalon filter 10, the monitor PDs 9 and 11, the beam splitter 23, the monitor PD 24, and the lens 41 are mounted on the front surface 12aa of the first substrate 12a of the Peltier module 12, and are controlled to the desired temperature by the Peltier module 12.

The laser element 4a of the chip-on-submount 4 is supplied with power from the outside via the lead (not illustrated), outputs the laser beam L1 to the signal light output port 1a side, and outputs a laser beam L41 to a side opposite to the signal light output port 1a. The power of the laser beam L1 and the power of the laser beam L41 are in a proportional relationship. The lens 5 collimates the laser beam L1 and outputs it to the optical isolator 6.

The optical isolator 6 allows the laser beam L1 to pass to the beam splitter 23 side. The beam splitter 23 outputs most of the laser beam L1 to the lens 2, and outputs a part of the laser beam L1 as the laser beam L11 to the monitor PD 24. The lens 2 condenses and couples the input laser beam L1 to the optical fiber 3.

The monitor PD 24 receives the laser beam L11 and outputs the current signal corresponding to the received light intensity. The current signal is transmitted to the controller and used for detection and control of the power of the laser beam L1.

The lens 41 collimates the laser beam L41 and outputs it to the beam splitter 8. The beam splitter 8 splits the laser beam L41 into laser beams L42 and L43, outputs the laser beam L42 to the monitor PD 9, and outputs the laser beam L43 to the etalon filter 10. The monitor PD 9 receives the laser beam L42 and outputs the current signal corresponding to the received light intensity. The current signal is transmitted to the controller and used for detection and control of power and wavelength of the laser beam L1.

The etalon filter 10 transmits the laser beam L43 with a transmittance corresponding to the wavelength, and outputs it to the monitor PD 11. The monitor PD 11 receives the laser beam L43 transmitted through the etalon filter 10 and outputs the current signal corresponding to the received light intensity. The current signal is transmitted to the controller and used for detection and control of the wavelength of the laser beam L1.

Here, patterns P2, P3, P6, P7, P21 to P23, and P41 to P43 made of a material different from that of the first substrate 12a are formed on the front surface 12aa of the first substrate 12a. The patterns P2, P3, P6, P7, P21 to P23, and P41 to P43 are made of, for example, at least one of the metal, the dielectric, or the resin according to the application.

The patterns P2, P3, P6, P7, and P21 to P23 have the same functions as those of the other embodiments. The patterns P41 and P42 function as the markers for positioning when the chip-on-submount 4 is mounted on the Peltier module 12 and fixed with the thermally conductive material. The patterns P41 and P42 also function as the flow stoppers until the thermally conductive material is cured. In this case, the patterns P41 and P42 preferably have thicknesses enough to function as the flow stoppers. The pattern P43 functions as the flow stopper until the adhesive is cured. In this case, the pattern P43 preferably has the thickness enough to function as the flow stopper.

According to the optical module 100D, the reduction in height can be realized, and the wiring, the soldering, and the alignment of the optical element to be mounted can be suitably realized.

### Sixth Embodiment

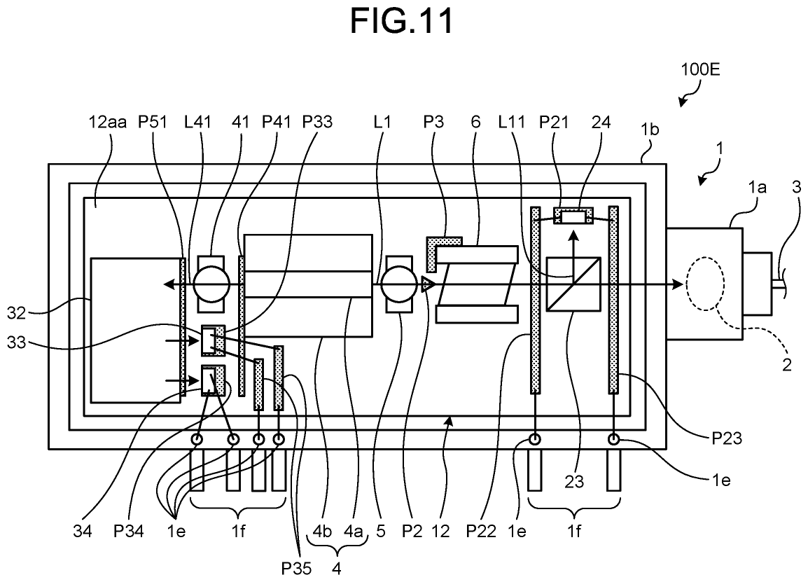

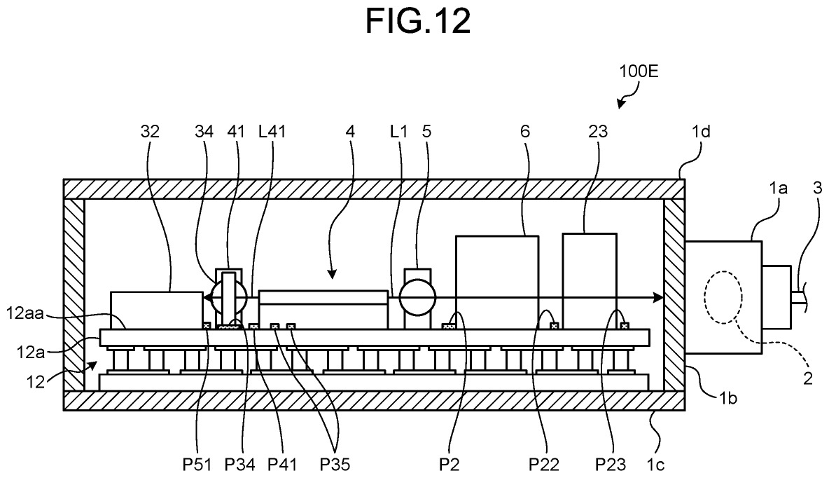

FIGS. 11 and 12 are respectively a schematic top view and a partially cutaway side view of the optical module according to a sixth embodiment.

This optical module 100E includes the housing 1 similar to that of the optical module illustrated in FIG. 1. The housing 1 includes a signal light output port 1a, a side wall 1b, a bottom plate 1c, an upper lid 1d, a wiring portion 1e, and a lead 1f.

The following components are accommodated inside the optical module 100E: the chip-on-submount 4, the lens 5, the optical isolator 6, the beam splitter 23, the monitor PD 24, the wavelength locker 32, the monitor PDs 33 and 34, the lens 41, and the Peltier module 12.

In the optical module 100E, the components are mounted inside the housing 1, and are hermetically sealed by attaching the upper lid 1d.

The optical module 100E is configured as the semiconductor laser module. Hereinafter, the configuration and function of each component will be described. However, the description of the components having the same configuration and function as those in other embodiments will be omitted as appropriate.

The Peltier module 12 absorbs heat or generates heat according to the direction in which the current flows.

The chip-on-submount 4, the lens 5, the optical isolator 6, the beam splitter 23, the monitor PD 24, the wavelength locker 32, the monitor PDs 33 and 34, and the lens 41 are mounted on the front surface 12aa of the first substrate 12a of the Peltier module 12, and are controlled to the desired temperature by the Peltier module 12.

The laser element 4a of the chip-on-submount 4 is supplied with power from the outside via the lead (not illustrated), outputs the laser beam L1 to the signal light output port 1a side, and outputs a laser beam L41 to a side opposite to the signal light output port 1a. The power of the laser beam L1 and the power of the laser beam L41 are in a proportional relationship.

The lens 5, the optical isolator 6, the beam splitter 23, and the monitor PD 24 have the same configuration and function as those in the other embodiments.

The lens 41 collimates the laser beam L41 and outputs it to the wavelength locker 32. The wavelength locker 32 branches the laser beam L41 into two, outputs one of the two to the monitor PD 33, and outputs the other one to the monitor PD 34 after causing the other one to pass through the filter whose transmission characteristic periodically changes with respect to the wavelength.

Each of the monitor PDs 33 and 34 receives each of two laser beams output from the wavelength locker 32 and outputs the current signal corresponding to the received light intensity. Each current signal is transmitted to the controller and used for detection and control of the wavelength of the laser beam L1.

Here, patterns P2, P3, P21 to P23, P33 to P35, P41, and P51 made of a material different from that of the first substrate 12a are formed on the front surface 12aa of the first substrate 12a. The patterns P2, P3, P21 to P23, P33 to P35, P41, and P51 are made of, for example, at least one of the metal, the dielectric, or the resin according to the application.

The patterns P2, P3, P21 to P23, P33 to P35, and P41 have the same functions as those of the other embodiments. The pattern P51 functions as the marker for alignment when the wavelength locker 32 is mounted on the Peltier module 12. In addition, in a case where the wavelength locker 32 is fixed to the Peltier module 12 with the adhesive, the pattern P51 also functions as the flow stopper until the adhesive is cured. In this case, the pattern P51 preferably has the thickness enough to function as the flow stopper.

According to the optical module 100E, the reduction in height can be realized, and the wiring, the soldering, and the alignment of the optical element to be mounted can be suitably realized.

In the above embodiment, since the base is not provided between the Peltier module 12 and the optical element, a contact area between a heat source such as the laser element 4a or the semiconductor optical amplifier 21a and the Peltier module 12 is reduced. Therefore, when the heat source is at an end of the Peltier module 12, the thermoelectric element 12c that does not effectively work for cooling exists, and power consumption may increase.

### First Modification

In the above case, by arranging the heat source near the center in a longitudinal direction of Peltier module 12, an increase in power consumption can be suppressed. For example, it is preferred that the center of the heat source be in a region including the center when the Peltier module 12 is divided into three in the longitudinal direction. Furthermore, it is more preferred that the center of the heat source be also in a region including the center when Peltier module 12 is divided into three with respect to a direction orthogonal to the longitudinal direction.

### Second Modification

In order to suppress the increase in power consumption of the Peltier module 12 and drive the Peltier module efficiently, the thermoelectric elements 12c may be densely arranged around a mounting position of the heat source.

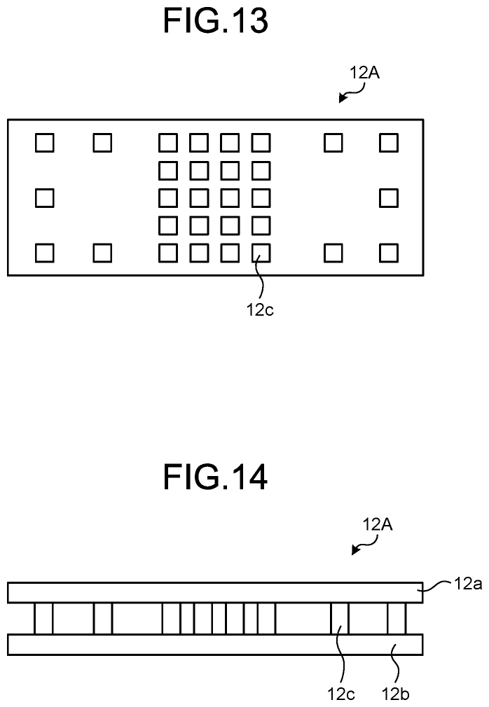

FIGS. 13 and 14 are respectively a schematic top view and a schematic side view of a Peltier module 12A according to a second modification. However, FIG. 13 is a simplified view except for the first substrate 12a and the wiring pattern 12d. Further, FIG. 14 is a simplified view except for the wiring pattern 12d. In FIG. 13, since the heat source is mounted near the center of the Peltier module 12A, the thermoelectric elements 12c are densely arranged near the center of the Peltier module 12A, and are sparsely arranged except in the center.

### Third Modification

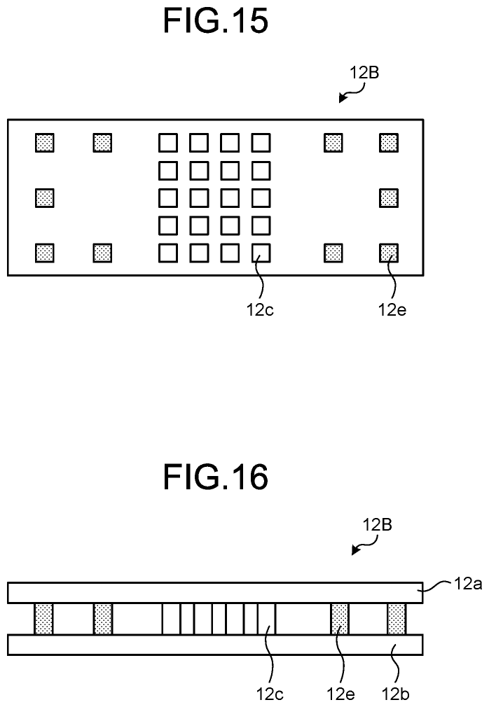

FIGS. 15 and 16 are respectively a schematic top view and a schematic side view of a Peltier module 12B according to a third modification. However, FIG. 15 is a simplified view except for the first substrate 12a and the wiring pattern 12d. FIG. 16 is a simplified view except for the wiring pattern 12d. In a Peltier module 12B according to the third modification, the thermoelectric elements 12c sparsely arranged in the Peltier module 12A according to the second modification are replaced with low thermally conductive members 12e formed of a material having a low thermal conductivity.

### Fourth Modification

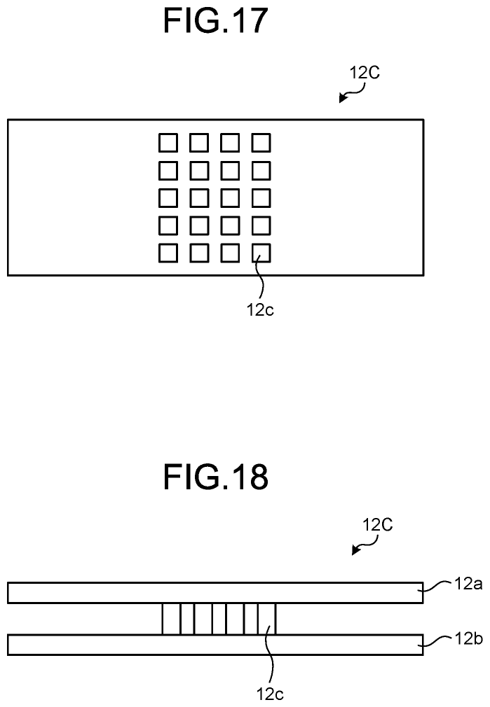

FIGS. 17 and 18 are respectively a schematic top view and a schematic side view of a Peltier module 12C according to a fourth modification. However, FIG. 17 is simplified view except for the first substrate 12a and the wiring pattern 12d. Further, FIG. 18 is a simplified view except for the wiring pattern 12d. In the Peltier module 12C according to the fourth modification, the thermoelectric elements 12c sparsely arranged in the Peltier module 12A according to the second modification are removed.

### Fifth Modification

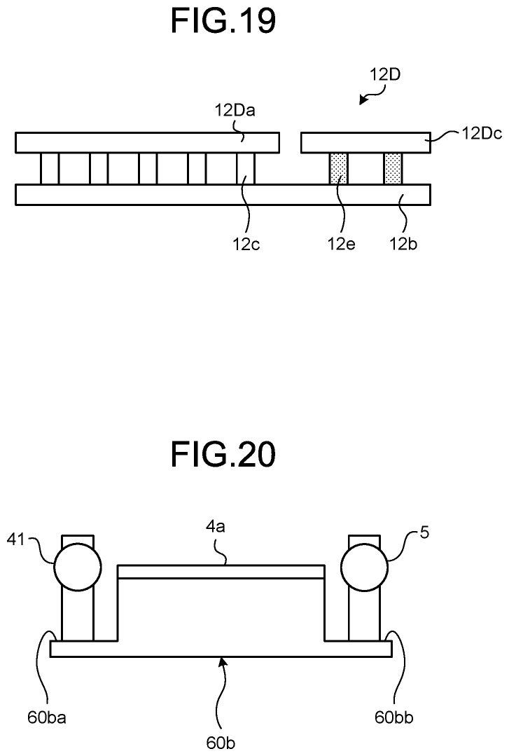

FIG. 19 is a schematic side view of a Peltier module 12D according to a fifth modification, and is a simplified view except for the wiring pattern 12d. In the fifth modification, only an optical element that requires temperature adjustment is mounted on a first substrate 12Da, and an optical element that does not require temperature adjustment is mounted on a third substrate l2Dc. Further, the thermoelectric elements 12c are arranged between the first substrate 12Da and the second substrate 12b, and the low thermally conductive member 12e is disposed between the third substrate 12Dc and the second substrate 12b.

In addition, since the base is removed and thus is directly affected by warpage of the first substrate 12a, optical coupling efficiency may be reduced due to positional deviation of the optical element.

### Sixth Modification

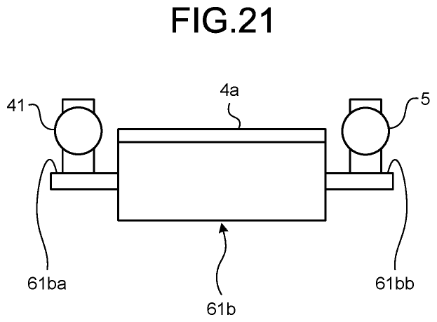

FIG. 20 is a schematic side view of the submount according to a sixth modification. FIG. 20 is a view illustrating a state in which the submount 4b is replaced with a submount 60b in the chip-on-submount 4 and the lenses 5 and 41 illustrated in FIG. 9. In the submount 60b, optical element installation portions 60ba and 60bb are provided in front of and behind the laser element 4a. In FIG. 20, since the lenses 5 and 41 largely affected by the positional deviation are mounted on the optical element installation portions 60ba and 60bb, influence of the warpage of the Peltier module 12 can be alleviated, and reduction in optical coupling efficiency can be suppressed. Further, the submount 60b may be replaced with a submount 61b according to a seventh modification as illustrated in FIG. 21. In the submount 61b, optical element installation portions 61ba and 61bb are provided in front of and behind the laser element 4a. The lenses 5 and 41 are mounted on the optical element installation portions 61ba and 61bb. The optical element installation portions 61ba and 61bb are provided to have a gap from the Peltier module 12.

The optical element mounted on the thermoelectric module is not limited to that of the above embodiment, and may be, for example, a modulator mounted on a TOSA. For example, the semiconductor optical amplifier 21a in FIG. 5 may be replaced with the modulator.

Further, in the present specification, the optical element and the pattern are “associated ” means that the pattern functions to have some technical influence on the optical element or implementation of the optical element, and performs a function associated with technical matters related to the optical element or the implementation of the optical element. As exemplified above, the function is, for example, that each pattern functions as the marker for positioning and alignment of each optical element, functions as the flow stopper for the thermally conductive material or adhesive having fluidity, functions as the marker for adjusting the optical axis, and functions as the wiring pattern, but is not limited to them. Note that the wiring pattern can be used to inject a current into the optical element or to apply a voltage to the optical element.

Further, the present invention is not limited by the above embodiments. The present invention also includes a configuration in which the above-described components are appropriately combined. In addition, further effects and modifications can be easily derived by those skilled in the art. Therefore, a wider aspect of the present invention is not limited to the above embodiments, and various modifications can be made.

According to the present invention, there is an effect that the height of the optical module can be reduced.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical module comprising:
an optical element; and
a thermoelectric module on which the optical element is mounted, wherein
the thermoelectric module includes a first substrate, a second substrate disposed to face the first substrate, and a plurality of thermoelectric elements provided between the first substrate and the second substrate, and a pattern made of a material different from a material of the first substrate is formed on a surface of the first substrate opposite to a back surface of the first substrate facing the second substrate, and
the optical element is mounted on the surface of the first substrate in association with the pattern.

2. The optical module according to claim 1, wherein the pattern is made of at least one of a metal, a dielectric, or a resin.

3. The optical module according to claim 1, wherein the pattern has a structure in which a gold (Au) layer and a layer including at least one of copper (Cu), titanium (Ti), nickel (Ni), palladium (Pd), and platinum (Pt) are laminated.

4. The optical module according to claim 1, wherein the optical element is a semiconductor laser element, a semiconductor optical amplifier, a modulator, a light receiving element, a lens, a prism, a beam splitter, a mirror, a filter, a planar lightwave circuit, or an optical isolator.

5. The optical module according to claim 1, wherein the optical element is a semiconductor laser element and is mounted on the first substrate via a submount, and the submount is fixed to the first substrate with a thermally conductive material.

6. The optical module according to claim 1, wherein the optical element is fixed to the first substrate with an epoxy resin.

7. The optical module according to claim 1, further comprising a housing that accommodates the optical element and the thermoelectric module.

8. A thermoelectric module comprising:
a first substrate;
a second substrate disposed to face the first substrate; and
a plurality of thermoelectric elements provided between the first substrate and the second substrate, wherein
a pattern made of a material different from a material of the first substrate is formed on a surface of the first substrate opposite to a back surface of the first substrate facing the second substrate.
